(19) United States
(12) Patent Application Publication
(10) Pub. No.: US 2025/0313982 A1
(43) Pub. Date: Oct. 9, 2025

(54) SUBSTRATE HOLDER AND SUBSTRATE PROCESSING APPARATUS

(71) Applicant: EBARA CORPORATION, Tokyo (JP)

(72) Inventors: Gaku YAMASAKI, Tokyo (JP); Shoichiro OGATA, Tokyo (JP)

(21) Appl. No.: 18/556,308

(22) PCT Filed: Dec. 28, 2022
(86) PCT No.: PCT/JP2022/048546

§ 371 Date: Jan. 10, 2025

(51) Int. Cl. C25D 17/06; H01L 21/687

(52) U.S. Cl. CPC C25D 17/06; H01L 21/687

(57) ABSTRACT

The present disclosure provides a substrate holder configured such that a mechanism for fixing a first holding material and a second holding material to each other can be operated in a non-contact manner. The substrate holder according to the present disclosure includes a first holding material, a second holding material for sandwiching and holding a substrate together with the first holding material, an engaging member provided on one of the first holding material and the second holding material, and an engaged member fixed to the other of the first holding material and the second holding material, the engaging member includes a magnet and is configured to be movable, by a magnetic force that acts on the magnet, between a locked position at which the engaging member engages with the engaged member to fix the first holding material and the second holding material to each other, and an unlocked position at which the engagement of the engaging member and the engaged member is released to release the fixing of the first holding material and the second holding material.

### TECHNICAL FIELD

The present invention relates to a substrate holder and a substrate processing apparatus.

### BACKGROUND ART

In a substrate processing apparatus for plating a substrate, a substrate holder for holding the substrate may be used. An example of such a substrate holder is disclosed in PTL 1. PTL 1 discloses a substrate holder comprising a front frame, a rear frame, and a clamper for clamping the front frame and the rear frame as shown in FIGS. 2A and 2B. In this substrate holder, when sandwiching the substrate between the frames, the clamper clamps the front frame and the rear frame, and the front frame and the rear frame are fixed to each other.

In the substrate holder of PTL 1, the clamper is exposed on a surface. For this reason, when this substrate holder is immersed in a processing solution such as a plating solution and taken out of the processing solution, the processing solution adheres to the clamper, and the processing solution, which is consumable, is taken out of a processing tank. In particular, the clamper is formed of fine parts in which many projections and depressions are formed, and hence the processing solution adhering to the clamper and taken out of the processing tank comparatively increases. Furthermore, during cleaning, it is also difficult to wash away the processing solution adhering to fine portions of the parts constituting the clamper.

To solve the problem, a substrate holder including a clamper to which any processing solution does not adhere is required. Such a substrate holder is disclosed in PTL 2. PTL 2 discloses, as shown in FIG. 5B, a substrate holder including a first holding member, a second holding member, a sealing member configured to form a space sealed inside the substrate holder, a pin, a ring that engages with the pin, and a moving mechanism configured to move the ring in a circumferential direction. In this substrate holder, the first holding member and the second holding member are fixed to each other by engaging the pin and the ring with each other. The pin and ring are provided inside a closed space. For this reason, the pin and ring are not in contact with the plating solution even when the substrate holder is immersed in the plating solution. Consequently, a mechanism for fixing the first holding member and the second holding member to each other prevents the plating solution from being taken out of the plating tank.

### CITATION LIST

### Patent Literature

PTL 1: Japanese Patent No. 6971922

PTL 2: Japanese Patent Laid-Open No. 2020-2389

### SUMMARY OF INVENTION

### Technical Problem

As described above, in a substrate holder disclosed in PTL 2, in order for a first holding member and a second holding member to be fixed to each other, a moving mechanism for moving a ring in a circumferential direction is required. In PTL 2, a rod member is disclosed as this moving mechanism. The rod member is configured to extend from an exterior of the substrate holder to an inner space of the substrate holder. The substrate holder of PTL 2 requires a passage connecting the exterior of the substrate holder and the inner space of the substrate holder for disposing the rod member. Consequently, a design in which a space where this passage is disposed is taken into consideration is required, which decreases a degree of freedom in the design of the substrate holder. Furthermore, in the substrate holder disclosed in PTL 2, it is assumed that a substrate to be held has a circular shape, and when the substrate has a rectangular shape, a structure becomes complicated and difficult to achieve.

If the mechanism for fixing the first holding member and the second holding member to each other is configured to be operable in a non-contact manner, the passage connecting the exterior of the substrate holder and the inner space of the substrate holder is not required, and the above problems can be solved. For this reason, a substrate holder configured such that the mechanism for fixing the first holding member and the second holding member to each other can be operated in the non-contact manner is required.

Therefore, one of objects of the present disclosure is to provide a substrate holder and a substrate processing apparatus, configured such that a mechanism for fixing a first holding material (first holding member) and a second holding material (second holding member) to each other can be operated in a non-contact manner.

### Solution to Problem

A substrate holder according to one embodiment is a substrate holder including a first holding material, a second holding material for sandwiching and holding a substrate together with the first holding material, an engaging member provided on one of the first holding material and the second holding material, and an engaged member fixed to the other of the first holding material and the second holding material, the engaging member includes a magnet and is configured to be movable, by a magnetic force that acts on the magnet, between a locked position at which the engaging member engages with the engaged member to fix the first holding material and the second holding material to each other, and an unlocked position at which the engagement of the engaging member and the engaged member is released to release the fixing of the first holding material and the second holding material.

### BRIEF DESCRIPTION OF DRAWINGS

FIG. 1 is an overall arrangement diagram of a substrate processing apparatus according to an embodiment of the present disclosure.

FIG. 2 is a front view schematically showing a substrate holder for use in the substrate processing apparatus of FIG. 1.

FIG. 3 is a cross-sectional perspective view of the substrate holder of FIG. 2.

FIG. 4 is an enlarged view of part A of FIG. 3.

FIG. 5 is a structural diagram showing the substrate holder and an opening/closing device of FIG. 2.

FIG. 6 is a cross-sectional view of the substrate holder of FIG. 2 when a first holding material and a second holding material are spaced apart.

FIG. 7 is a front view of the substrate holder of FIG. 2 for indicating a position of a sealing member.

FIG. 8A is a cross-sectional view along line B-B of FIG. 7.

FIG. 8B is a cross-sectional view of a substrate holder according to a comparative form.

FIG. 9A is a cross-sectional view along line C-C of FIG. 7.

FIG. 9B is a cross-sectional view of the substrate holder according to the comparative form.

FIG. 10 is a cross-sectional view of the substrate holder of FIG. 2 when a hook is at a locked position.

FIG. 11 is a cross-sectional view of the substrate holder of FIG. 2 when the hook is at an unlocked position.

FIG. 12 is a diagram showing a wiring configuration inside the substrate holder of FIG. 2.

FIG. 13 is a cross-sectional view of a substrate holder according to an embodiment other than the substrate holder of FIG. 2.

FIG. 14 is a cross-sectional view along line D-D of FIG. 13.

FIG. 15A is a structural diagram showing the substrate holder and an opening/closing device of FIG. 13.

FIG. 15B is a structural diagram showing the substrate holder and the opening/closing device of FIG. 13.

### DESCRIPTION OF EMBODIMENTS

Hereinafter, embodiments of the present invention will be described with reference to the drawings. In the drawings described below, the same or corresponding components are denoted with the same signs and are not described in duplicate.

### Substrate Processing Apparatus 100

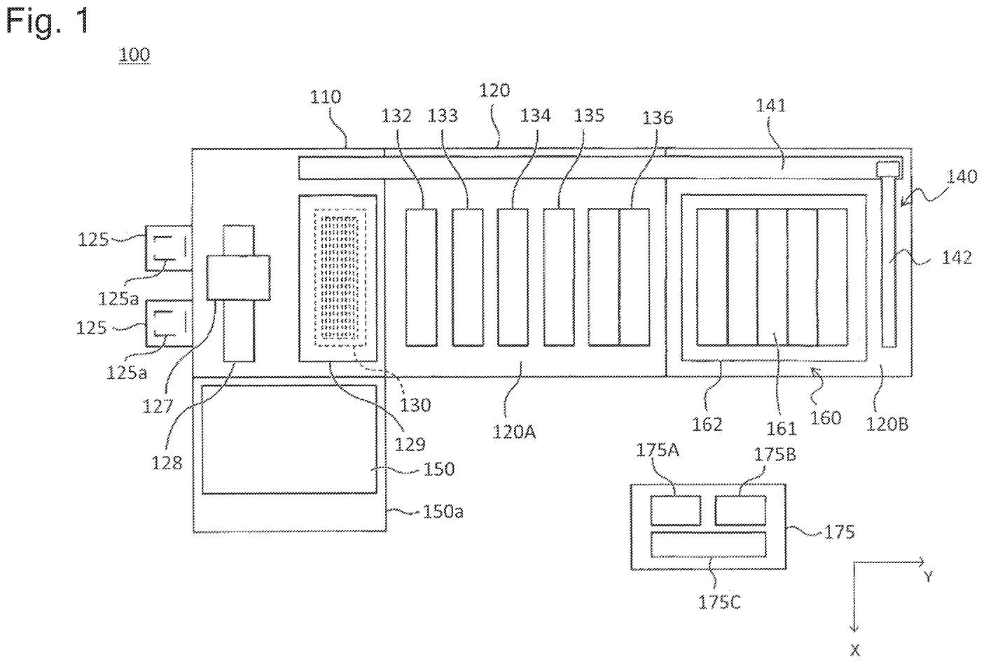

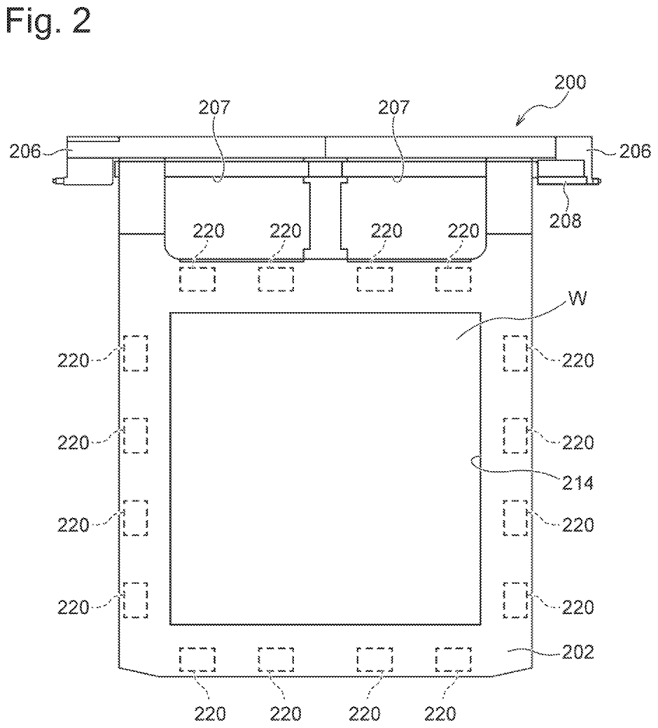

FIG. 1 is an overall arrangement diagram of a substrate processing apparatus 100 in which a substrate holder 200 according to one embodiment of the present disclosure is used. As an example, the substrate processing apparatus 100 is a plating apparatus for performing plating on a substrate W. Note that substrate holders 200 and 400 described later are for use in the substrate processing apparatus 100 but may be used for a substrate processing apparatus other than the substrate processing apparatus 100. In the present disclosure, the substrate processing apparatus means an apparatus that performs some processing on the substrate W. Referring to FIG. 1, the substrate processing apparatus 100 is roughly divided into a loader/unloader 110 that loads the substrate W into the substrate holder 200 (see FIG. 2) or unloads the substrate W from the substrate holder 200, a processor 120 that processes the substrate W, and a cleaner 150a. The processor 120 further includes a preprocessor/postprocessor 120A that performs preprocessing and postprocessing of the substrate W, and a plating processor 120B that performs plating on the substrate W. Examples of the substrate W processed with the substrate processing apparatus 100 include a square substrate, a circular substrate, and the like. Examples of the square substrate include a polygonal glass substrate having a rectangular shape or the like, a liquid crystal substrate, a printed circuit board, and another polygonal plating object. Examples of the circular substrate include a semiconductor wafer, a glass substrate and another circular plating object.

The loader/unloader 110 includes two cassette tables 125 and a loading/unloading station 129. Each of the cassette tables 125 is configured to be able to be loaded with a cassette 125a that houses a substrate such as a semiconductor wafer, a glass substrate, a liquid crystal substrate, and a printed circuit board. In the loading/unloading station 129, the substrate W is attached to and detached from the substrate holder 200 by a known method. Further, a stocker 130 for stocking the substrate holder 200 is provided in the vicinity of (for example, below) the loading/unloading station 129. A transfer robot 127 for transferring the substrate W is disposed between the cassette tables 125 and the loading/unloading station 129. The transfer robot 127 is configured to be travelable by a traveling mechanism 128 and transfers the substrate W between the cassette tables 125 and the loading/unloading station 129.

The cleaner 150a includes a cleaning device 150 that cleans and dries the plated substrate W. The transfer robot 127 is configured to transfer the plated substrate W to the cleaning device 150 and to take the cleaned substrate W out of the cleaning device 150.

The preprocessor/postprocessor 120A includes a pre-wet module 132, a pre-soak module 133, a first rinse module 134, a blowing module 135, and a second rinse module 136. In the pre-wet module 132, the substrate W is immersed in pure water. In the pre-soak module 133, an oxide film on the surface of a conductive layer such as a seed layer formed on the surface of the substrate W is etched away. In the first rinse module 134, the pre-soaked substrate W is cleaned with a cleaning solution (pure water or the like), together with the substrate holder 200. In the blowing module 135, the cleaned substrate W is drained. In the second rinse module 136, the plated substrate W is cleaned with a cleaning solution, together with the substrate holder 200. The pre-wet module 132, the pre-soak module 133, the first rinse module 134, the blowing module 135 and the second rinse module 136 are arranged in this order. The configuration of the preprocessor/postprocessor 120A of the substrate processing apparatus 100 is an example, and the configuration of the preprocessor/postprocessor 120A of the substrate processing apparatus 100 is not limited, and another configuration may be adopted.

The plating processor 120B includes a plating module 160 for performing plating on the substrate W. The plating module 160 includes a plurality of plating tanks 161 including an overflow tank 162. Each of the plating tanks 161 immerses the substrate W in a plating solution held internally to plate the surface of the substrate W by copper plating or the like. Here, a type of plating solution is not particularly limited, and various plating solutions are used depending on applications. Further, the pre-wet module 132, the pre-soak module 133, the first rinse module 134, the blowing module 135, the second rinse module 136 and the plating module 160 include a processing tank for housing the substrate holder 200 in order to perform the above-described processing on the substrate W or the substrate holder 200. In the present disclosure, a tank capable of housing the substrate holder 200 is referred to as a processing tank. The plating tank 161 is an example of the processing tank.

Referring again to FIG. 1, the substrate processing apparatus 100 further includes a substrate holder transfer device 140 for transferring the substrate holder 200, for example, by adopting a linear motor system. The substrate holder transfer device 140 includes a rail 141 and a transfer device 142. The transfer device 142 travels on the rail 141. The transfer device 142 has a function of transferring the substrate holder 200 between the loading/unloading station 129, the pre-wet module 132, the pre-soak module 133, the first rinse module 134, the blowing module 135, the second rinse module 136, and the plating tanks 161.

The substrate processing apparatus 100 includes a control system 175 configured to control each of the above-described parts. The control system 175 includes a memory 175B that stores predetermined program, a central processing unit (CPU) 175A that executes the program of the memory 175B, and a controller 175C that controls each part of the substrate processing apparatus 100 based on a command from the CPU 175A. The controller 175C can perform, for example, transfer control of the transfer robot 127, attaching/detaching control of the substrate W to/from the substrate holder 200 in the loading/unloading station 129, transfer control of the transfer device 142, control of plating current and plating time in each plating tank 161, control of an opening size of an anode mask (not shown) disposed in each plating tank 161 and an opening size of a regulation plate (not shown), and the like. Further, the control system 175 is configured to be able to communicate with an unshown upper control system that overall controls the substrate processing apparatus 100 and other related apparatuses and can exchange data with a database provided by the upper control system. Here, a storage medium constituting the memory 175B stores various types of setting data and various types of program such as plating program. As the storage medium, a known medium may be used, for example, a memory such as ROM or RAM that can be read by a computer, or a disk-like storage medium such as a hard disk, CD-ROM, DVD-ROM or flexible disk.

### Substrate Holder 200

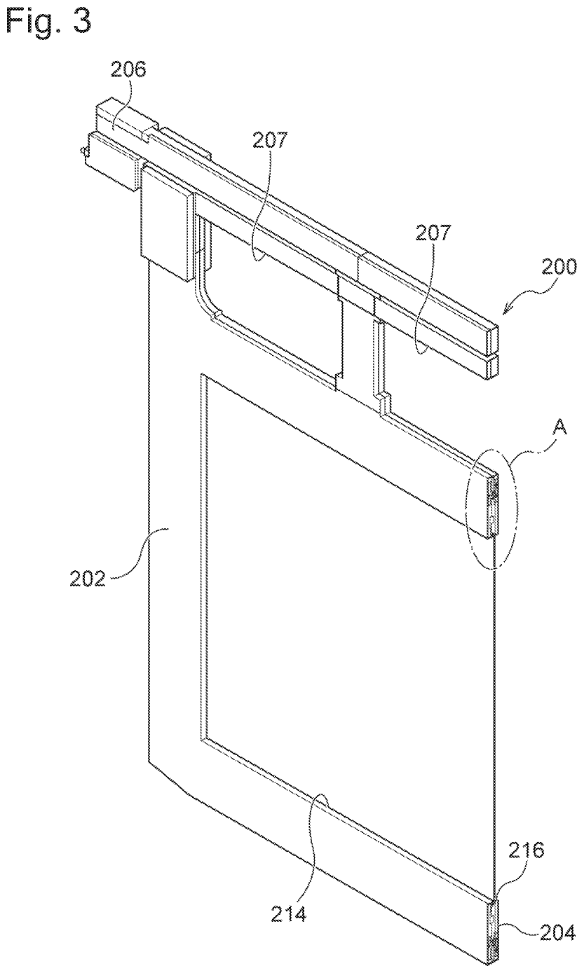

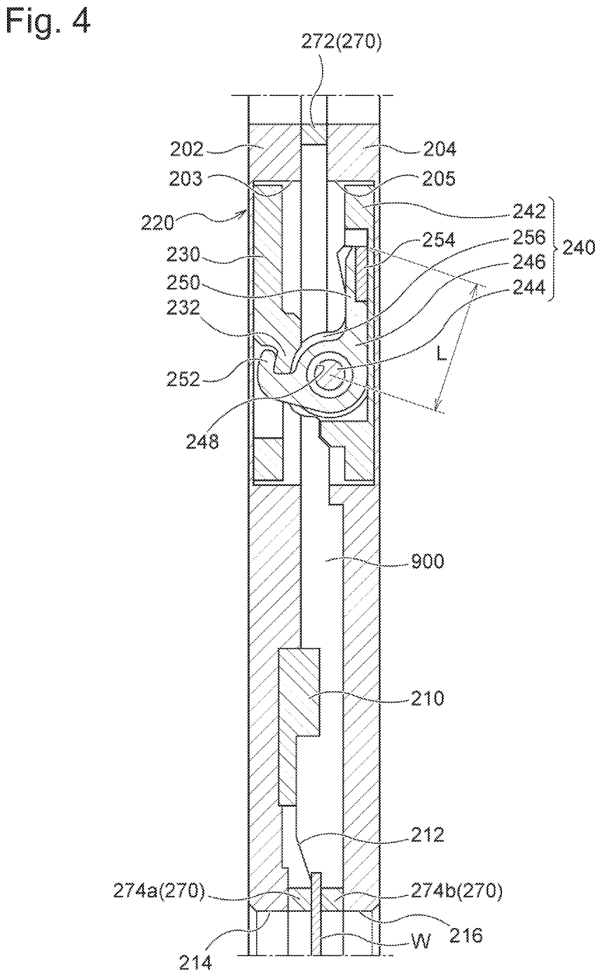

Next, with reference to FIGS. 2 to 4, a configuration of the substrate holder 200 will be described in more detail. FIG. 2 is a front view schematically showing the substrate holder 200. FIG. 3 is a cross-sectional perspective view of the substrate holder 200. FIG. 4 is an enlarged view of part A of FIG. 3. The substrate holder 200 is a holder for holding the substrate W. In FIG. 2, the substrate holder 200 holds the substrate W having a quadrangular shape as an example. However, the substrate holder 200 is not limited to this configuration and may hold the substrate W having another shape such as a round shape.

As shown in FIGS. 2 to 4, the substrate holder 200 includes, as an example, a rectangular flat first holding material 202 and a rectangular flat second holding material 204 configured to sandwich and hold the substrate W together with the first holding material 202 (see FIGS. 3 and 4). In other words, the substrate holder 200 is configured so that the substrate W can be sandwiched and held between the first holding material 202 and the second holding material 204. The first holding material 202 and the second holding material 204 are made of titanium as an example.

Further, the first holding material 202 and the second holding material 204 are formed with openings 214 and 216, respectively (see FIGS. 3 and 4). Thereby, the substrate holder 200 can expose the substrate W from the respective openings 214 and 216. Consequently, the substrate processing apparatus 100 can perform various types of processing such as plating on the surface of the substrate W exposed from the openings 214 and 216. In another embodiment according to the present disclosure, the opening 214 is formed only in the first holding material 202, and the substrate W may be exposed only from the opening 214 of the first holding material 202. The openings 214 and 216 have a shape corresponding to the shape of the substrate W. For example, in the substrate holder 200 of FIG. 2, the openings 214 and 216 are square. However, in another embodiment according to the present disclosure, the openings 214 and 216 may have another shape such as a round shape.

Further, as shown in FIG. 2, the substrate holder 200 includes a pair of handles 206 on an upper portion of the holder, as an example. Two openings 207 are formed between the pair of handles 206. The transfer device 142 (see FIG. 1) grasps the substrate holder 200 at the openings 207 and transfers the substrate holder 200 with a vertical posture to each processing tank. The vertical posture is a posture when the handles 206 are arranged above and the substrate W has a plate surface extending in a vertical direction. Further, when the substrate holder 200 is transferred and the substrate W held in the substrate holder 200 is processed in each processing tank, the handles 206 are arranged above a handle receiving member (not shown) of each processing tank. For this reason, in the substrate processing apparatus 100, the surface of the substrate W is processed in a state where the substrate holder 200 is supported with the vertical posture.

The substrate holder 200 includes, as an example, an external contact 208 (see FIG. 2), a busbar 210 (see FIG. 4), and an electrical contact 212 (see FIG. 4). The external contact 208 is provided on the handle 206 and is electrically connected to the busbar 210 by an unshown electrical wiring or busbar. The busbar 210 is disposed inside a closed space 900 as described later and is electrically connected to the electrical contact 212. Further, the electrical contact 212 is configured to be in contact with an outer circumferential portion of the substrate W held by the substrate holder 200. In the substrate processing apparatus 100, when the substrate holder 200 is transferred to the plating tank 161, the external contact 208 contacts an electrical contact (not shown) provided on the handle receiving member of the plating tank 161, to supply a current from an external power supply to the external contact 208. Then, the current is supplied to the surface of the substrate W via the busbar 210 and the electrical contact 212, and the substrate W is plated.

Referring to FIG. 2, the substrate holder 200 includes, as an example, a plurality of (16 in the example of FIG. 2) clampers 220. The plurality of clampers 220 are provided around the openings 214 and 216 to surround the substrate W. The clampers 220 have a function of fixing the first holding material 202 and the second holding material 204 to each other. Since the clampers 220 are provided inside the substrate holder 200, in FIGS. 2, 7 and 12, the clampers 220 are shown by dashed lines. The detailed configuration of the clampers 220 will be described below. Referring to FIG. 4, the clamper 220 includes, for example, an engaged member 230 and an engaging member assembly 240.

The engaged member 230 is a thin plate member having a substantially rectangular parallelepiped shape. The engaged member 230 fits in a recess 203 formed in the first holding material 202 and is fixed to the first holding material 202. The engaged member 230 includes a claw 232. The claw 232 extends toward the engaging member assembly 240 and has a tip bent. In other words, the claw 232 is configured to be engaged with an engaging portion 252 of a hook 246 by rotation of the hook 246 described later.

The engaging member assembly 240 is fixed to the second holding material 204 so as to face the engaged member 230. More specifically, the engaging member assembly 240 includes a hook base 242, a rotary shaft 244, and the hook (an example of an engaging member) 246. The hook base 242 is a thin plate member having a substantially rectangular parallelepiped shape and is configured to support the rotary shaft 244. The hook base 242 fits in a recess 205 formed in the second holding material 204 and is fixed to the second holding material 204. The hook base 242 is made of stainless steel as an example. The rotary shaft 244 is inserted in a shaft hole 248 provided in the hook 246, to rotatably support the hook 246. That is, the hook 246 is configured to be rotatable about the rotary shaft 244. The rotary shaft 244 extends in an orientation in which the plate surface of the substrate W extends. The rotary shaft 244 is made of stainless steel as an example. The hook 246 has an L-shape and includes a lever 250 at one end and the engaging portion 252 at the other end. The engaging portion 252 extends toward the engaged member 230, and the engaging portion 252 has a tip bent to be able to engage with the claw 232. The lever 250 extends in a direction perpendicular to a direction in which the rotary shaft 244 extends.

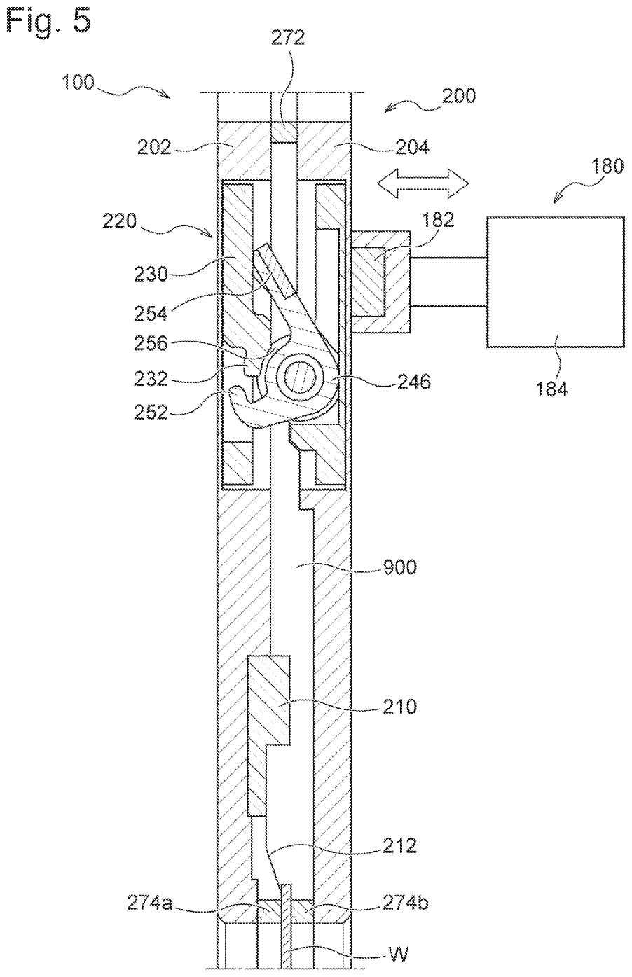

The hook 246 is configured to rotate movably between a locked position (position shown in FIG. 4) and an unlocked position (position shown in FIG. 5). Then, when the hook 246 is at the locked position, the engaging portion 252 of the hook 246 engages with the claw 232 of the engaged member 230 to fix the first holding material 202 and the second holding material 204 to each other. When the hook 246 is at the unlocked position, the engagement of the engaging portion 252 of the hook 246 with the claw 232 of the engaged member 230 is released to release the fixing of the first holding material 202 and the second holding material 204. In other words, in the substrate holder 200, moving the hook 246 to the locked position fixes the first holding material 202 and the second holding material 204 to each other, and moving the hook 246 to the unlocked position releases the fixing of the first holding material 202 and the second holding material 204.

The hook 246 also includes a magnet 254. The magnet 254 is mounted to the lever 250 of the hook 246. Thereby, a magnetic force that acts on the magnet 254 allows the hook 246 to rotate about the rotary shaft 244. That is, the magnetic force that acts on the magnet 254 allows the hook 246 to move between the locked position and the unlocked position. Further, a length L between the center of the rotary shaft 244 and a position of the magnet 254 farthest from the center of the rotary shaft 244 is preferably longer. This is because the longer length L can allow the hook 246 to move with a smaller magnetic force by a leverage principle. The length L is preferably 10 mm or more.

As described above, in the substrate holder 200, the engaged member 230 is fixed to the first holding material 202, and the engaging member assembly 240 is fixed to the second holding material 204. Alternatively, the substrate holder 200 may not include such a configuration. In another embodiment according to the present disclosure, the engaged member 230 may be fixed to the second holding material 204, and the engaging member assembly 240 may be fixed to the first holding material 202.

The engaging member assembly 240 includes a biasing member 256 as an example (see FIG. 4). The biasing member 256 has a function of biasing the hook 246 in a direction toward the locked position. More specifically, the biasing member 256 is a torsion spring. When a biasing force of the biasing member 256 acts on the hook 246, the hook 246 is located at the locked position unless the magnetic force acts on the magnet 254 of the hook 246. In other words, the biasing member 256 can prevent the hook 246 from detaching from the claw 232 by applying force to the hook 246 so as to maintain the engagement of the hook 246.

FIG. 5 is a structural diagram showing the substrate holder 200 and an opening/closing device 180. Referring to FIG. 5, the substrate processing apparatus 100 includes the opening/closing device 180 as an example. The opening/closing device 180 is provided, for example, in the loading/unloading station 129 (see FIG. 1). Further, the opening/closing device 180 is provided to be located opposite the first holding material 202 via the second holding material 204. The opening/closing device 180 has a function of exerting the magnetic force on the magnet 254 of the hook 246 for movement between the locked position and the unlocked position. More specifically, the opening/closing device 180 includes a magnet 182 and an actuator 184 for exerting the magnetic force on the magnet 254 of the hook 246. The actuator 184 is a linear actuator as an example and has a function of moving the magnet 182 between a first position (position shown in FIG. 5) and a second position farther from the magnet 182 than the first position. The magnet 182 is configured to exert a repulsive force against the magnet 254 of the hook 246. When the actuator 184 moves the magnet 182 from the second position to the first position, the repulsive force acting against the magnet 254 of the hook 246 strengthens. The repulsive force acting against the magnet 254 of the hook 246 thus exceeds the biasing force of the biasing member 256, and the hook 246 moves from the locked position to the unlocked position. As a result, the fixing of the first holding material 202 and the second holding material 204 by the clampers 220 is released. When the actuator 184 moves the magnet 182 from the first position to the second position, the repulsive force acting against the magnet 254 of the hook 246 weakens. Consequently, the biasing force of the biasing member 256 exceeds the repulsive force acting against the magnet 254, and the hook 246 moves from the unlocked position to the locked position. Thus, the clampers 220 fix the first holding material 202 and the second holding material 204 to each other. Thus, in the substrate holder 200, the hook 246 is operated with the magnetic force. In other words, the substrate holder 200 is configured so that the hook 246 can be operated in a non-contact manner. The opening/closing device 180 may include a configuration other than the above configuration as long as the magnetic force can act on the magnet 254 of the hook 246 to move the hook between the locked position and the unlocked position.

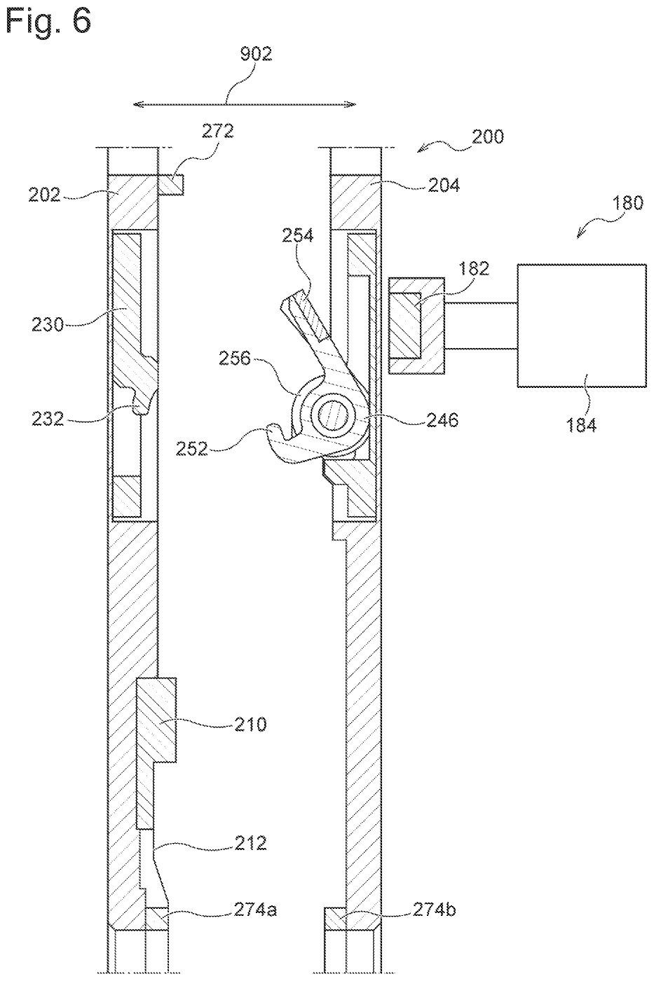

Further, when the substrate W is removed from the substrate holder 200, the first holding material 202 is moved in an opening/closing direction 902 while the fixing with the clampers 220 is released (see FIG. 6). Thereby, the first holding material 202 is spaced apart from the second holding material 204, and the substrate W sandwiched between the first holding material 202 and the second holding material 204 can be removed. In the present disclosure, the opening/closing direction 902 of the substrate holder 200 means a direction in which the first holding material 202 and the second holding material 204 are brought close or spaced apart when the substrate holder 200 releases or holds the substrate W.

Referring again to FIG. 4, the substrate holder 200 includes an outer seal 272 and two inner seals 274a and 274b. The outer seal 272 and the two inner seals 274a and 274b are included in a sealing member 270. The outer seal 272 is mounted to the first holding material 202 or the second holding material 204 and is configured to be in contact with the first holding material 202 and the second holding material 204. For this reason, the outer seal 272 has a function of sealing between the first holding material 202 and the second holding material 204. The inner seal 274a is mounted to the first holding material 202 and is configured to be in contact with the first holding material 202 and the substrate W. Consequently, the inner seal 274a has a function of sealing between the first holding material 202 and the substrate W. Further, the inner seal 274b is mounted to the second holding material 204 and is configured to be in contact with the second holding material 204 and the substrate W. For this reason, the inner seal 274b has a function of sealing between the second holding material 204 and the substrate W.

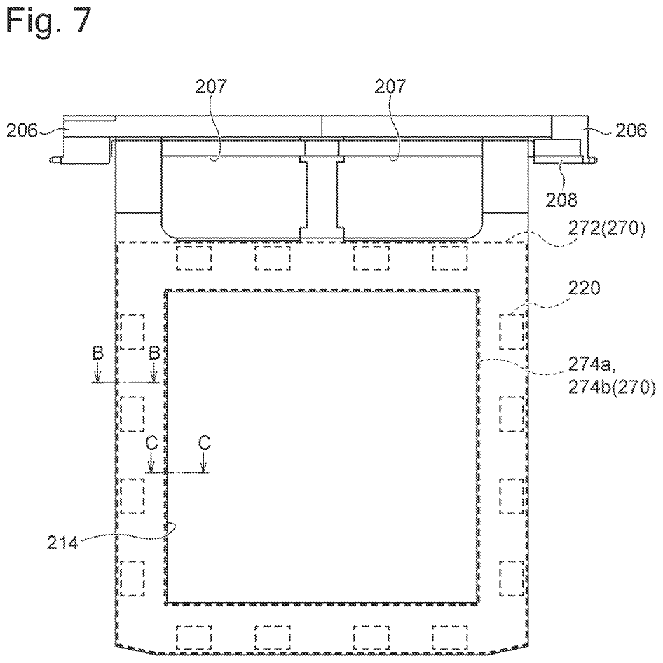

Next, reference is made to FIG. 7. FIG. 7 is a front view of the substrate holder 200 for showing a position of the sealing member 270. In FIG. 7, the outer seal 272 and two inner seals 274a and 274b are hidden behind the first holding material 202, and hence their positions are shown with dashed lines. In FIG. 7, the inner seals 274a and 274b appear to overlap each other and are shown as a single dashed line. As shown in FIG. 7, the outer seal 272 and the inner seals 274a and 274b are both formed in a substantially ring shape. The inner seals 274a and 274b are provided to surround the openings 214 and 216 along a circumferential edge portion of the substrate W. The outer seal 272 is provided outside the inner seals 274a and 274b so that the plurality of clampers 220 are located between the outer seal 272 and the inner seals 274a and 274b.

In the substrate holder 200, when the first holding material 202 and the second holding material 204 hold the substrate W, the first holding material 202, the second holding material 204, the outer seal 272 and the two inner seals 274a and 274b are configured to form the closed space 900 (see FIG. 4). Then, the hook 246 and the engaged member 230 are provided inside the closed space 900. For this reason, when the substrate W and the substrate holder 200 are immersed in a processing solution such as a plating solution, the hook 246 and the engaged member 230 are not in contact with the processing solution. Consequently, the processing solution is prevented from adhering to the hook 246 or the engaged member 230 and being taken out of the processing tank. Furthermore, since the processing solution does not adhere to the hook 246 and the engaged member 230, it is not necessary to wash away the processing solution from the hook 246 and the engaged member 230 when cleaning the substrate holder 200.

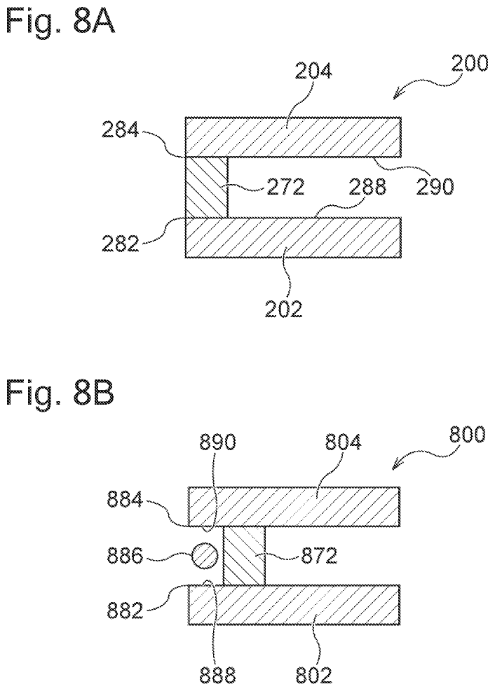

Next, refer to FIG. 8A. FIG. 8A is a cross-sectional view along line B-B of FIG. 7. Referring to FIG. 8A, the outer seal 272 is disposed in contact with an outer end 282 of a surface 288 of the first holding material 202 that faces the second holding material 204. Further, the outer seal 272 is disposed in contact with an outer end 284 of a surface 290 of the second holding material 204 that faces the first holding material 202. An effect of the outer seal 272 disposed in this way will be described in comparison with a substrate holder 800 according to a comparative form shown in FIG. 8B.

FIG. 8B is a cross-sectional view of the substrate holder 800 according to the comparative form and shows a portion corresponding to the B-B cross-section. In the substrate holder 800, an outer seal 872 is not disposed in contact with an outer end 882 of a surface 888 of a first holding material 802 that faces a second holding material 804 or an outer end 884 of a surface 890 of the second holding material 804 that faces the first holding material 802. In this case, in a portion in contact with the processing solution, a region 886 surrounded with the outer seal 872, the surface 888 of the first holding material 802 and the surface 890 of the second holding material 804 is formed. The region 886 surrounded in this way on three sides is easy to collect liquid. For this reason, when the substrate holder 800 is pulled up from the processing tank, the processing solution accumulates in the region 886, and more processing solution may be taken out of the processing tank.

In contrast, in the case of the substrate holder 200 shown in FIG. 8A, the outer seal 272 is disposed in contact with the outer end 282 of the surface 288 of the first holding material 202 or the outer end 284 of the surface 290 of the second holding material 204. For this reason, a portion corresponding to the region 886 of the substrate holder 800 is not formed in the substrate holder 200. Therefore, the substrate holder 200 can reduce an amount of processing solution taken out of the processing tank.

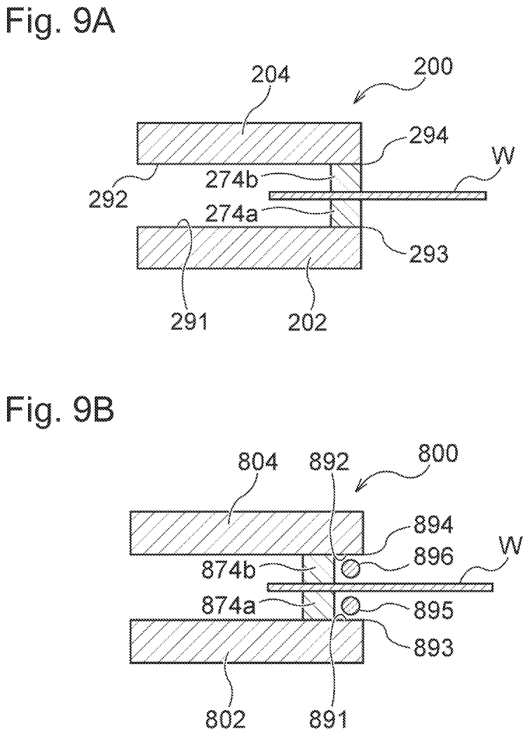

Next, refer to FIG. 9A. FIG. 9A is a cross-sectional view along line C-C of FIG. 7. Referring to FIG. 9A, the inner seal 274a is disposed in contact with an inner end 293 of a surface 291 of the first holding material 202 that faces the substrate W. Further, the inner seal 274b is disposed in contact with an inner end 294 of a surface 292 of the second holding material 204 that faces the substrate W. An effect of the inner seals 274a and 274b arranged in this way will be described in comparison with the substrate holder 800 according to the comparative form shown in FIG. 9B.

FIG. 9B is a cross-sectional view of the substrate holder 800 according to the comparative form and shows a portion corresponding to the C-C cross-section. In the substrate holder 800, an inner seal 874a is not disposed in contact with an inner end 893 of a surface 891 of the first holding material 802 that faces the substrate W. In this case, in a portion in contact with the processing solution, a region 895 surrounded with the inner seal 874a, the surface 891 of the first holding material 802 and the substrate W is formed. Since the region 895 is surrounded on three sides, the region is easy to collect liquid. Further, the inner seal 874b is not disposed in contact with an inner end 894 of a surface 892 of the second holding material 804 that faces the substrate W. In this case, in the portion in contact with the processing solution, a region 896 surrounded with the inner seal 874b, the surface 892 of the second holding material 804 and the substrate W is formed. Since the region 896 is surrounded on three sides, the region is easy to collect liquid. For this reason, when the substrate holder 800 is pulled up from the processing tank, the processing solution accumulates in the regions 895 and 896, and more processing solution may be taken out of the processing tank.

In contrast, in the substrate holder 200 shown in FIG. 9A, the inner seal 274a is disposed in contact with the inner end 293, and the inner seal 274b is disposed in contact with the inner end 294. For this reason, portions corresponding to the regions 895 and 896 of the substrate holder 800 are not formed in the substrate holder 200. Therefore, the substrate holder 200 can reduce the amount of the processing solution taken out of the processing tank.

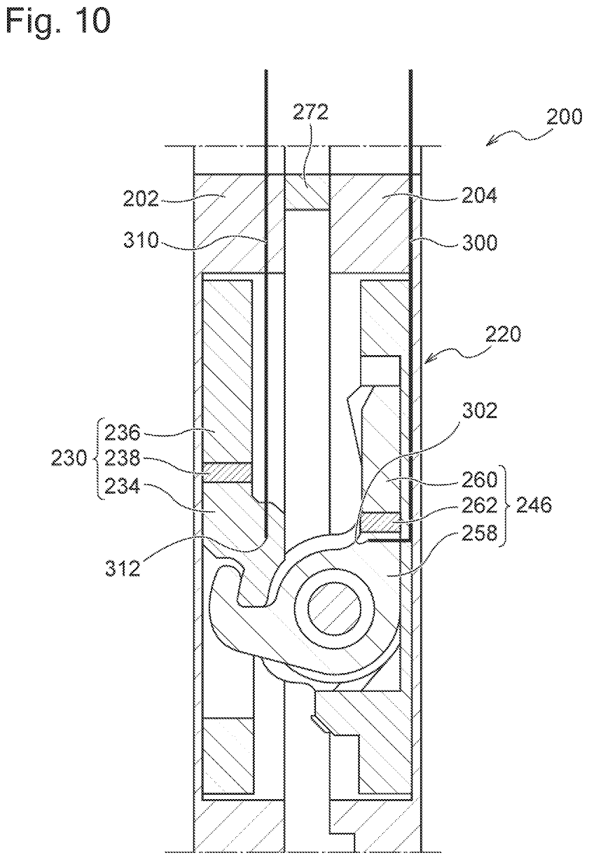

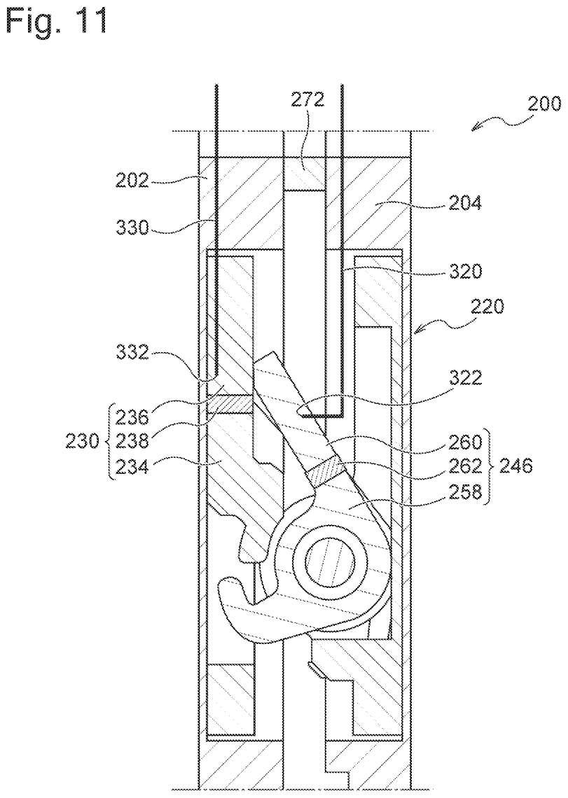

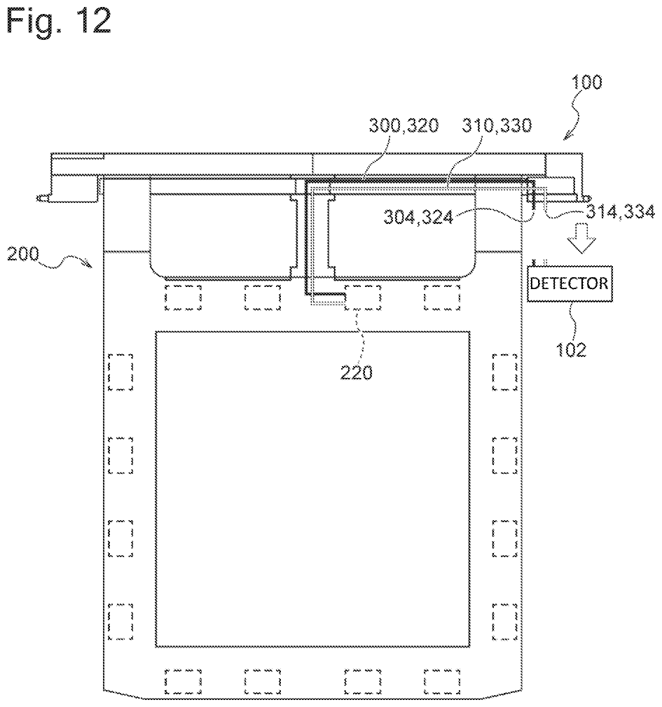

Next, with reference to FIGS. 10 to 12, a mechanism for confirming the position of the hook 246 will be described. FIG. 10 is a cross-sectional view of the substrate holder 200 when the hook 246 is at the locked position. FIG. 11 is a cross-sectional view of the substrate holder 200 when the hook 246 is at the unlocked position. FIG. 12 is a diagram showing a wiring configuration inside the substrate holder 200. In FIG. 10, a third wiring 320 and a fourth wiring 330 are not shown, and in FIG. 11, a first wiring 300 and a second wiring 310 are not shown.

Referring to FIGS. 10 and 11, the substrate holder 200 includes the first wiring 300 (see FIG. 10), the second wiring 310 (see FIG. 10), the third wiring 320 (see FIG. 11), and the fourth wiring 330 (see FIG. 11). The hook 246 includes a first contacting portion 258, a second contacting portion 260, and an insulating portion 262. The first contacting portion 258 and the second contacting portion 260 are made of stainless steel as an example. The insulating portion 262 electrically insulates between the first contacting portion 258 and the second contacting portion 260. More specifically, the insulating portion 262 is made of a resin such as PEEK as an example. The engaged member 230 includes a first contacted portion 234, a second contacted portion 236, and an insulating portion 238. The first contacted portion 234 and the second contacted portion 236 are made of stainless steel as an example. The insulating portion 238 electrically insulates between the first contacted portion 234 and the second contacted portion 236. More specifically, the insulating portion 238 is made of a resin such as PEEK as an example.

The first wiring 300 includes a first end 302 (see FIG. 10) electrically connected to the first contacting portion 258 and a second end 304 (see FIG. 12) exposed to the outside of the substrate holder 200. The second wiring 310 includes a first end 312 (see FIG. 10) electrically connected to the first contacted portion 234 and a second end 314 (see FIG. 12) exposed to the outside of the substrate holder 200. The third wiring 320 includes a first end 322 (see FIG. 11) electrically connected to the second contacting portion 260 and a second end 324 (see FIG. 12) exposed to the outside of the substrate holder 200. The fourth wiring 330 includes a first end 332 (see FIG. 11) electrically connected to the second contacted portion 236, and a second end 334 (see FIG. 12) exposed to the outside of the substrate holder 200.

Further, as shown in FIG. 10, when the hook 246 is at the locked position, the first contacting portion 258 is configured to be in contact with and electrically connected to the first contacted portion 234. As shown in FIG. 11, when the hook 246 is not located at the locked position, the first contacting portion 258 is configured not to be in contact with or electrically connected to the first contacted portion 234. The substrate holder 200 includes such a configuration, and hence only when the hook 246 is at the locked position, the second end 304 of the first wiring 300 is electrically connected to the second end 314 of the second wiring 310 via the first wiring 300, the first contacting portion 258, the first contacted portion 234 and the second wiring 310. For this reason, if the second end 304 of the first wiring 300 is electrically continuous with the second end 314 of the second wiring 310, it is guaranteed that the hook 246 is at the locked position. Specifically, an operator can confirm whether or not the hook 246 is at the locked position by confirming continuity between the second end 304 of the first wiring 300 and the second end 314 of the second wiring 310. In other words, the operator can confirm whether or not the clampers 220 fix the first holding material 202 and the second holding material 204 by confirming the continuity.

Further, as shown in FIG. 11, the second contacting portion 260 is configured to be in contact with and electrically connected to the second contacted portion 236, when the hook 246 is at the unlocked position. As shown in FIG. 10, the second contacting portion 260 is configured not to be in contact with or electrically connected to the second contacted portion 236, when the hook 246 is not at the unlocked position. The substrate holder 200 includes such a configuration, and hence only when the hook 246 is at the unlocked position, the second end 324 of the third wiring 320 is electrically connected to the second end 334 of the fourth wiring 330 via the third wiring 320, the second contacting portion 260, the second contacted portion 236 and the fourth wiring 330. For this reason, if the second end 324 of the third wiring 320 is electrically continuous with the second end 334 of the fourth wiring 330, it is guaranteed that the hook 246 is at the unlocked position. That is, the operator can confirm whether or not the hook 246 is at the unlocked position by confirming continuity between the second end 324 of the third wiring 320 and the second end 334 of the fourth wiring 330. In other words, the operator can confirm whether or not the fixing with the clampers 220 is released by confirming the continuity.

Further, the substrate processing apparatus 100 may include a detector 102 as shown in FIG. 12 in the loading/unloading station 129. The detector 102 has a function of confirming the continuity between the second end 304 of the first wiring 300 and the second end 314 of the second wiring 310, and the continuity between the second end 324 of the third wiring 320 and the second end 334 of the fourth wiring 330. Thereby, the substrate processing apparatus 100 can detect that the clampers 220 fix the first holding material 202 and the second holding material 204 and that the fixing with the clampers 220 is released, by using the detector 102.

### Substrate Holder 400

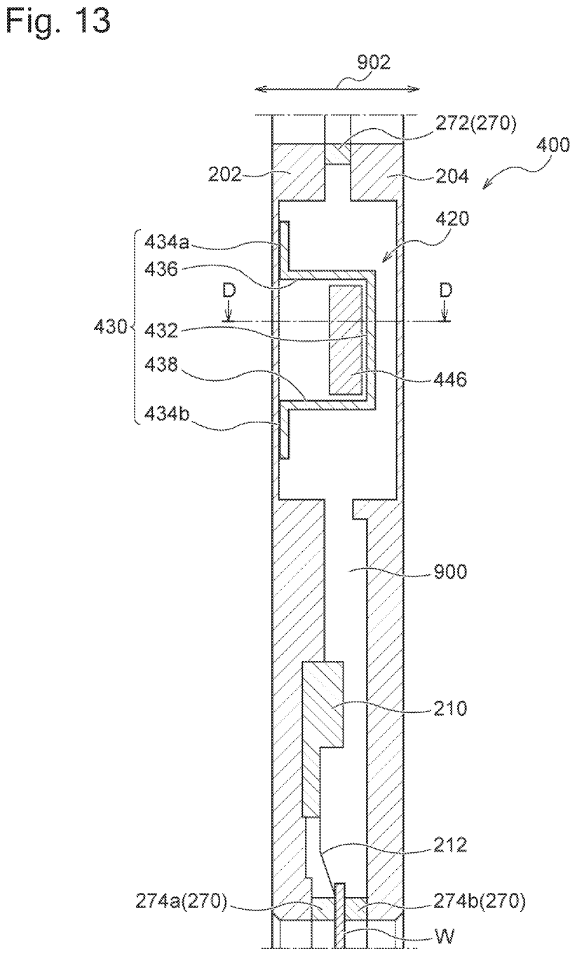

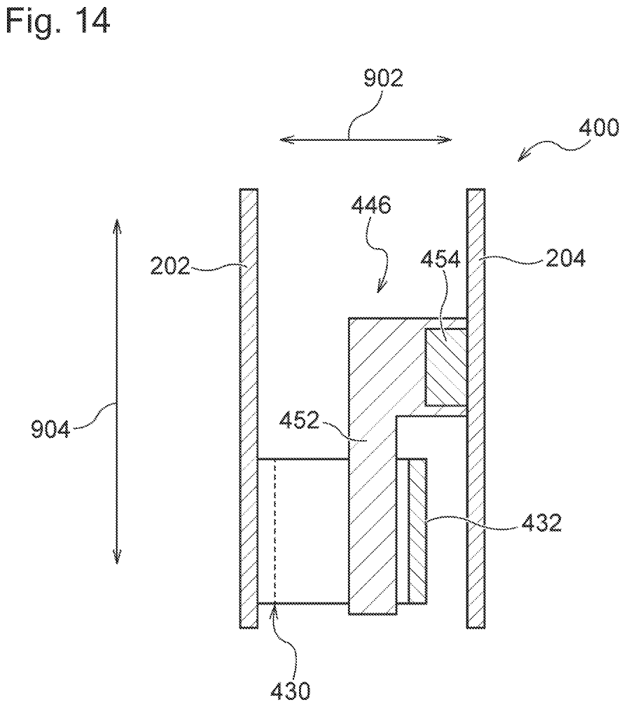

FIG. 13 is a cross-sectional view of the substrate holder 400 according to an embodiment other than the substrate holder 200. FIG. 14 is a cross-sectional view along line D-D of FIG. 13. Referring to FIGS. 13 and 14, the configuration of the substrate holder 400 will be described below. The substrate holder 400 includes, in a part of the holder, a common configuration with the substrate holder 200. For this reason, the substrate holder 400 will be described mainly regarding a portion different from the substrate holder 200, and the common configuration is denoted with the same signs and is not described.

Referring to FIG. 13, the substrate holder 400 includes, for example, a clamper 420 instead of the clamper 220 provided in the substrate holder 200. The clamper 420 includes an engaged member 430 and an engaging member 446.

The engaged member 430 is a member formed by bending a thin plate. The engaged member 430 includes two ends 434a and 434b fixed to the first holding material 202, a regulation wall 432, a first wall 436, and a second wall 438. The ends 434a and 434b, the regulation wall 432, the first wall 436, and the second wall 438 have a flat plate shape as an example. The first wall 436 connects the end 434a and the regulation wall 432 and is orthogonal to the end 434a and the regulation wall 432. The second wall 438 connects the end 434b and the regulation wall 432 and is orthogonal to the end 434b and the regulation wall 432. The regulation wall 432 extends on a plane perpendicular to the opening/closing direction 902 of the substrate holder 200. From another point of view, the regulation wall 432 extends on a plane parallel to the plate surface of the substrate W.

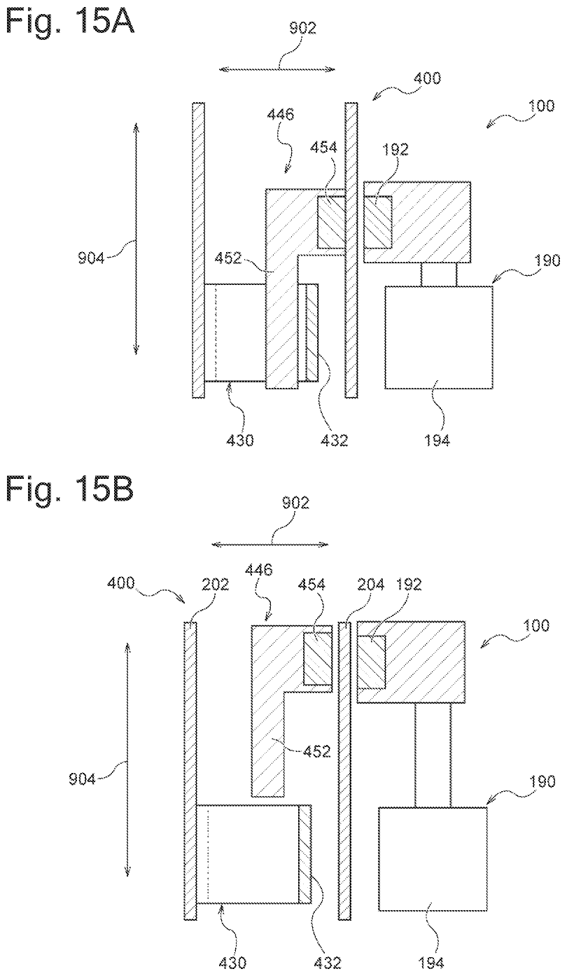

The engaging member 446 is provided in the second holding material 204. More specifically, the engaging member 446 is mounted to the second holding material 204 so that the member can move in a perpendicular direction 904 to the second holding material 204, although movement in the opening/closing direction 902 with respect to the second holding material 204 is regulated (see FIG. 14). Then, the engaging member 446 moves in the perpendicular direction 904 and can move between a locked position (position shown in FIG. 15A) and an unlocked position (position shown in FIG. 15B). The engaging member 446 also includes a magnet 454. Thereby, the engaging member 446 can move between the locked position and the unlocked position with a magnetic force that acts on the magnet 454. Note that the perpendicular direction 904 means a direction perpendicular to the opening/closing direction 902.

The engaging member 446 also includes a rod-shaped portion 452. The rod-shaped portion 452 and the regulation wall 432 are configured such that the regulation wall 432 contacts the rod-shaped portion 452 to regulate movement of the rod-shaped portion 452 in the opening/closing direction 902 to the first holding material 202, when the engaging member 446 is at the locked position (position shown in FIG. 15A). The rod-shaped portion 452 and the regulation wall 432 are also configured to prevent the regulation wall 432 from regulating the movement of the rod-shaped portion 452 in the opening/closing direction 902 to the first holding material 202, when the engaging member 446 is at the unlocked position (position shown in FIG. 15B).

Then, refer to FIGS. 15A and 15B. FIG. 15A is a structural diagram showing the substrate holder 400 and an opening/closing device 190 and shows a case where the engaging member 446 is at the locked position. FIG. 15B is a structural diagram showing the substrate holder 400 and the opening/closing device 190 and shows a case where the engaging member 446 is at the unlocked position. When the substrate processing apparatus 100 processes the substrate W by use of the substrate holder 400, the substrate processing apparatus 100 may include the opening/closing device 190 shown in FIGS. 15A and 15B instead of the opening/closing device 180 of FIG. 5. The opening/closing device 190 is provided to be located opposite the first holding material 202 via the second holding material 204. The opening/closing device 190 has a function of exerting a magnetic force on the magnet 454 of the engaging member 446 to move the engaging member between the locked position and the unlocked position. More specifically, the opening/closing device 190 includes a magnet 192 for exerting the magnetic force on the magnet 454 of the engaging member 446, and an actuator 194. The actuator 194 is a linear actuator as an example and has a function of moving the magnet 192 between a first position and a second position. The first position is such a position of the magnet 192 (position shown in FIG. 15A) that the magnet 192 can face the magnet 454 via the second holding material 204 when the engaging member 446 is at the locked position. The second position is such a position of the magnet 192 (position shown in FIG. 15B) that the magnet 192 can face the magnet 454 via the second holding material 204 when the engaging member 446 is at the unlocked position.

When the actuator 194 moves the magnet 192 from the first position (position shown in FIG. 15A) to the second position (position shown in FIG. 15B), the magnet 454 is pulled by attraction of the magnet 192, and the engaging member 446 moves from the locked position to the unlocked position. Consequently, the fixing of the first holding material 202 and the second holding material 204 by the clamper 420 is released. When the actuator 194 moves the magnet 192 from the second position (position shown in FIG. 15B) to the first position (position shown in FIG. 15A), the magnet 454 is pulled by attraction of the magnet 192, and the engaging member 446 moves from the unlocked position to the locked position. Consequently, the clamper 420 fixes the first holding material 202 and the second holding material 204 to each other.

Thus, in the substrate holder 400, the engaging member 446 is operated with the magnetic force. In other words, the substrate holder 400 is configured such that the engaging member 446 can be operated in a non-contact manner. The opening/closing device 190 may include any configuration other than the above configuration as long as the magnetic force can be exerted on the magnet 454 of the engaging member 446 to move the engaging member between the locked position and the unlocked position.

### Supplements

Some or all of the above embodiments may also be described as supplements below but are not limited to the following.

### Supplement 1

A substrate holder according to Supplement 1 is a substrate holder including a first holding material, a second holding material for sandwiching and holding a substrate together with the first holding material, an engaging member provided on one of the first holding material and the second holding material, and an engaged member fixed to the other of the first holding material and the second holding material, wherein the engaging member includes a magnet and is configured to be movable, by a magnetic force that acts on the magnet, between a locked position at which the engaging member engages with the engaged member to fix the first holding material and the second holding material to each other, and an unlocked position at which the engagement of the engaging member and the engaged member is released to release the fixing of the first holding material and the second holding material.

In the substrate holder according to Supplement 1, the magnetic force acts on the magnet and allows the engaging member to move between the locked position and the unlocked position. In response to this movement, the first holding material and the second holding material are fixed to each other, or the fixing of the first holding material and the second holding material is released. Specifically, the substrate holder according to Supplement 1 is configured so that the engaging member can be operated in a non-contact manner.

### Supplement 2

The substrate holder according to Supplement 2 is the substrate holder according to Supplement 1, which further includes a sealing member, wherein the first holding material, the second holding material and the sealing member are configured to form a closed space, when the first holding material and the second holding material hold the substrate, and the engaging member and the engaged member are provided inside the closed space.

In the substrate holder according to Supplement 2, when the substrate and the substrate holder are immersed in a processing solution such as a plating solution, the engaging member and the engaged member are not in contact with the processing solution. For this reason, the processing solution is prevented from adhering to the engaging member or the engaged member and being taken out of a processing tank. Furthermore, since the processing solution does not adhere to the engaging member and the engaged member, it is not necessary to wash away the processing solution from the engaging member and the engaged member.

### Supplement 3

The substrate holder according to Supplement 3 is the substrate holder according to Supplement 2, wherein the sealing member includes an inner seal configured to be in contact with the first holding material or the second holding material, and the substrate, and an outer seal configured to be in contact with the first holding material and the second holding material.

The substrate holder according to Supplement 3 can seal between the first holding material or the second holding material and the substrate, with the inner seal. Furthermore, the substrate holder can seal between the first holding material and the second holding material, with the outer seal.

### Supplement 4

The substrate holder according to Supplement 4 is the substrate holder according to Supplement 3, wherein the outer seal is disposed in contact with an outer end of a surface of the first holding material that faces the second holding material, or an outer end of a surface of the second holding material that faces the first holding material.

When the outer seal is disposed in contact with the outer end of the surface of the first holding material or the outer end of the surface of the second holding material, a region surrounded with the outer seal, the surface of the first holding material and the surface of the second holding material is not formed in a portion that is in contact with the processing solution. For this reason, since the substrate holder according to Supplement 4 does not have such a region, an amount of processing solution taken out of the processing tank can be reduced.

### Supplement 5

The substrate holder according to Supplement 5 is the substrate holder according to Supplement 3 or 4, wherein the inner seal is disposed in contact with an inner end of a surface of the first holding material that faces the substrate, or an inner end of a surface of the second holding material that faces the substrate.

When the inner seal is disposed in contact with the inner end of the surface of the first holding material that faces the substrate, or the inner end of the surface of the second holding material that faces the substrate, the region surrounded with the inner seal, the surface of the first holding material or the surface of the second holding material and the substrate is not formed in the portion in contact with the processing solution. For this reason, since the substrate holder according to Supplement 5 does not have such a region, the amount of processing solution taken out of the processing tank can be reduced.

### Supplement 6

The substrate holder according to Supplement 6 is the substrate holder according to any one of Supplements 1 to 5, wherein the engaging member is a hook configured to be rotatable about a rotary shaft, the engaged member includes a claw configured to be engaged with the hook by rotation of the hook, the hook engages with the claw when the engaging member is at the locked position, and the hook is not engaged with the claw when the engaging member is at the unlocked position.

According to the substrate holder of Supplement 6, the first holding material and the second holding material are fixed to each other by engaging the hook with the claw. Further, by releasing the engagement of the hook with the claw, the fixing of the first holding material and the second holding material is released.

### Supplement 7

The substrate holder according to Supplement 7 is the substrate holder according to any one of Supplements 1 to 6, including a biasing member for biasing the engaging member in a direction toward the locked position.

In the substrate holder according to Supplement 7, the engaging member is at the locked position unless the magnetic force acts on the magnet of the engaging member.

### Supplement 8

The substrate holder according to Supplement 8 is the substrate holder according to any one of Supplements 1 to 5, wherein the engaging member includes a rod-shaped portion, the engaging member is mounted to the second holding material to regulate movement of the engaging member in an opening/closing direction of the substrate holder to the second holding material while the engaging member is movable in a perpendicular direction perpendicular to the opening/closing direction, the engaged member includes a regulation wall that contacts the rod-shaped portion to regulate movement of the rod-shaped portion in the opening/closing direction, the engaged member being fixed to the first holding material, the regulation wall regulates the movement of the rod-shaped portion in the opening/closing direction when the engaging member is at the locked position, and the regulation wall does not regulate the movement of the rod-shaped portion in the opening/closing direction, when the engaging member is at the unlocked position.

### Supplement 9

The substrate holder according to Supplement 9 is the substrate holder according to any one of Supplements 1 to 8, wherein the engaging member includes a first contacting portion, and the engaged member includes a first contacted portion, the substrate holder including a first wiring and a second wiring, wherein the first wiring includes a first end electrically connected to the first contacting portion, and a second end exposed to outside of the substrate holder, the second wiring includes a first end electrically connected to the first contacted portion, and a second end exposed to the outside of the substrate holder, the first contacting portion is configured to be electrically connected to the first contacted portion when the engaging member is at the locked position, and the first contacting portion is configured not to be electrically connected to the first contacted portion when the engaging member is not located at the locked position.

According to the substrate holder of Supplement 9, when the engaging member is at the locked position, the second end of the first wiring and the second end of the second wiring are electrically connected via a plurality of members. For this reason, if the second end of the first wiring is electrically continuous with the second end of the second wiring, it is guaranteed that the engaging member is at the locked position. Specifically, an operator can confirm whether or not the engaging member is at the locked position by confirming continuity between the second end of the first wiring and the second end of the second wiring.

### Supplement 10

The substrate holder according to Supplement 10 is the substrate holder according to any one of Supplements 1 to 9, wherein the engaging member includes a second contacting portion, and the engaged member includes a second contacted portion, the substrate holder including a third wiring and a fourth wiring, wherein the third wiring includes a first end electrically connected to the second contacting portion, and a second end exposed to outside of the substrate holder, the fourth wiring includes a first end electrically connected to the second contacted portion, and a second end exposed to the outside of the substrate holder, the second contacting portion is configured to be electrically connected to the second contacted portion when the engaging member is at the unlocked position, and the second contacting portion is configured not to be electrically connected to the second contacted portion when the engaging member is not located at the unlocked position.

According to the substrate holder of Supplement 10, when the engaging member is at the unlocked position, the second end of the third wiring and the second end of the fourth wiring are electrically connected via a plurality of members. For this reason, if the second end of the third wiring is electrically continuous with the second end of the fourth wiring, it is guaranteed that the engaging member is at the unlocked position. Specifically, the operator can confirm whether or not the engaging member is at the unlocked position by confirming continuity between the second end of the third wiring and the second end of the fourth wiring.

### Supplement 11

A substrate processing apparatus according to Supplement 11 includes the substrate holder according to any one of Supplements 1 to 10, and an opening/closing device that exerts a magnetic force on the magnet of the substrate holder for movement between the locked position and the unlocked position.

In the substrate processing apparatus according to Supplement 11, the opening/closing device can move the engaging member of the substrate holder between the locked position and the unlocked position.

### Supplement 12

A substrate processing apparatus according to Supplement 12 includes the substrate holder according to any one of Supplements 1 to 10, and a plating module for performing plating on the substrate.

The substrate processing apparatus according to Supplement 12 can perform the plating on the substrate held by the substrate holder.

### REFERENCE SIGNS LIST

100: substrate processing apparatus
102: detector
160: plating module
180, 190: opening/closing device
200: substrate holder
202: first holding material
204: second holding material
220: clamper
230: engaged member
232: claw
234: first contacted portion
236: second contacted portion
240: engaging member assembly
246: hook
254: magnet
256: biasing member
258: first contacting portion
260: second contacting portion
270: sealing member
272: outer seal
274a, 274b: inner seal
282, 284: outer end
293, 294: inner end
300: first wiring
310: second wiring
320: third wiring
330: fourth wiring
400: substrate holder
420: clamper
430: engaged member
432: regulation wall
446: engaging member
452: rod-shaped portion
454: magnet
900: closed space
902: opening/closing direction
904: perpendicular direction
W: substrate

1. A substrate holder comprising:
a first holding material,
a second holding material for sandwiching and holding a substrate together with the first holding material,
an engaging member provided on one of the first holding material and the second holding material, and
an engaged member fixed to the other of the first holding material and the second holding material, wherein the engaging member includes a magnet, and is configured to be movable, by a magnetic force that acts on the magnet, between a locked position at which the engaging member engages with the engaged member to fix the first holding material and the second holding material to each other, and an unlocked position at which the engagement of the engaging member and the engaged member is released to release the fixing of the first holding material and the second holding material.

2. The substrate holder according to claim 1, further comprising:
a sealing member, wherein the first holding material, the second holding material and the sealing member are configured to form a closed space, when the first holding material and the second holding material hold the substrate, and
the engaging member and the engaged member are provided inside the closed space.

3. The substrate holder according to claim 2, wherein the sealing member comprises:
an inner seal configured to be in contact with the first holding material or the second holding material, and the substrate, and
an outer seal configured to be in contact with the first holding material and the second holding material.

4. The substrate holder according to claim 3, wherein the outer seal is disposed in contact with an outer end of a surface of the first holding material that faces the second holding material, or an outer end of a surface of the second holding material that faces the first holding material.

5. The substrate holder according to claim 3,
wherein the inner seal is disposed in contact with an inner end of a surface of the first holding material that faces the substrate, or an inner end of a surface of the second holding material that faces the substrate.

6. The substrate holder according to claim 1, wherein the engaging member is a hook configured to be rotatable about a rotary shaft,
the engaged member includes a claw configured to be engaged with the hook by rotation of the hook,
the hook engages with the claw when the engaging member is at the locked position, and
the hook is not engaged with the claw when the engaging member is at the unlocked position.

7. The substrate holder according to claim 1, comprising:
a biasing member for biasing the engaging member in a direction toward the locked position.

8. The substrate holder according to claim 1, wherein the engaging member includes a rod-shaped portion,
the engaging member is mounted to the second holding material to regulate movement of the engaging member in an opening/closing direction of the substrate holder to the second holding material while the engaging member is movable in a perpendicular direction perpendicular to the opening/closing direction,
the engaged member includes a regulation wall that contacts the rod-shaped portion to regulate movement of the rod-shaped portion in the opening/closing direction, the engaged member being fixed to the first holding material,
the regulation wall regulates the movement of the rod-shaped portion in the opening/closing direction when the engaging member is at the locked position, and
the regulation wall does not regulate the movement of the rod-shaped portion in the opening/closing direction when the engaging member is at the unlocked position.

9. The substrate holder according to claim 1, wherein the engaging member includes a first contacting portion, and
the engaged member includes a first contacted portion,
the substrate holder comprising a first wiring and a second wiring, wherein the first wiring includes a first end electrically connected to the first contacting portion, and a second end exposed to outside of the substrate holder,
the second wiring includes a first end electrically connected to the first contacted portion, and a second end exposed to the outside of the substrate holder,
the first contacting portion is configured to be electrically connected to the first contacted portion when the engaging member is at the locked position, and
the first contacting portion is configured not to be electrically connected to the first contacted portion when the engaging member is not located at the locked position.

10. The substrate holder according to claim 1, wherein the engaging member includes a second contacting portion, and
the engaged member includes a second contacted portion,
the substrate holder comprising a third wiring and a fourth wiring, wherein the third wiring includes a first end electrically connected to the second contacting portion, and a second end exposed to the outside of the substrate holder,
the fourth wiring includes a first end electrically connected to the second contacted portion, and a second end exposed to the outside of the substrate holder,
the second contacting portion is configured to be electrically connected to the second contacted portion when the engaging member is at the unlocked position, and
the second contacting portion is configured not to be electrically connected to the second contacted portion when the engaging member is not located at the unlocked position.

11. A substrate processing apparatus comprising:
the substrate holder according to claim 1, and
an opening/closing device that exerts a magnetic force on the magnet of the substrate holder for movement between the locked position and the unlocked position.

12. A substrate processing apparatus comprising:
the substrate holder according to claim 1, and
a plating module for performing plating on the substrate.
